(19) United States
(12) Patent Application Publication
(10) Pub. No.: US 2024/0332134 A1
(43) Pub. Date: Oct. 3, 2024

(54) METHODS AND APPARATUS TO MITIGATE ELECTROMIGRATION IN INTEGRATED CIRCUIT PACKAGES

(71) Applicant: Intel Corporation, Santa Clara, CA (US)

(72) Inventors: Liang He, Chandler, AZ (US); Jung Kyu Han, Chandler, AZ (US); Gang Duan, Chandler, AZ (US)

(21) Appl. No.: 18/193,182

(22) Filed: Mar. 30, 2023

(51) Int. Cl. H01L 23/495; H01L 21/768; H01L 23/00; H01L 23/15; H01L 23/528; H01L 23/532

(52) U.S. Cl. CPC H01L 23/49513; H01L 21/76898; H01L 23/15; H01L 23/5283; H01L 23/53228; H01L 24/03; H01L 24/06; H01L 24/11; H01L 24/14; H01L 2224/05147; H01L 2224/06131; H01L 2224/13109; H01L 2224/13111; H01L 2224/13139; H01L 2224/13147; H01L 2224/13155; H01L 2224/14131

(57) ABSTRACT

Methods and apparatus to mitigate electromigration are disclosed. A disclosed example integrated circuit (IC) package includes a dielectric substrate, a contact pad at least partially extending though or positioned on the dielectric substrate, the contact pad including copper, and a metal interconnect coupled to the contact pad, the interconnect including indium.

### FIELD OF THE DISCLOSURE

This disclosure relates generally to integrated circuit (IC) packages and, more particularly, to methods and apparatus to mitigate electromigration in IC packages.

### BACKGROUND

Semiconductor packages utilizing glass core technology can provide improved high frequency performance due to lower loss and improved signal isolation in comparison to silicon. In particular, glass core technology utilizes a glass substrate with interconnects extending therethrough. In comparison to packages based on an organic core, packages utilizing glass core technology can mitigate warpage and, thus, can enable a greater degree of heterogenous disaggregation.

### BRIEF DESCRIPTION OF THE DRAWINGS

FIG. 1 is a cross sectional view of an example semiconductor package in accordance with teachings of this disclosure.

FIG. 2 is an example process flow to produce examples disclosed herein.

FIGS. 3A-3E depict example stages in a manufacturing process to produce examples disclosed herein.

FIGS. 4A and 4B are detailed cross-sectional views of microball implementations.

FIG. 5 is a flowchart representative of an example method to produce examples disclosed herein.

FIG. 6 is a top view of a wafer including dies that may be included in an integrated circuit (IC) package constructed in accordance with teachings disclosed herein.

FIG. 7 is a cross-sectional side view of an IC device that may be included in an IC package constructed in accordance with teachings disclosed herein.

FIG. 8 is a cross-sectional side view of an IC package that may include a microball structure, in accordance with teachings disclosed herein.

FIG. 9 is a cross-sectional side view of an IC device assembly that may include an IC package constructed in accordance with teachings disclosed herein.

FIG. 10 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Methods and apparatus to mitigate electromigration are disclosed. Semiconductor packages utilizing glass core technology can provide improved high frequency performance due to lower loss and better signal isolation in comparison to utilization of an organic core. Typically, in known implementations, microball (MBL) technology for first level interconnects (FLI) can be implemented with electroless nickel/electroless palladium/immersion gold (ENEPIG) as a surface finish. However, because shock and sway can cause an increased risk of glass breakage to a glass core, such implementations are not typically compatible with the aforementioned glass core technology. Further, in known implementations, tin copper (SnCu) solder may not meet Imax requirement.

Examples disclosed herein enable reliable interconnect joints/coupling that can be advantageous with glass core technology implementations. In particular, examples disclosed herein enable improved mitigation of electron migration and, thus, can improve an overall reliability of semiconductor/IC packages. According to examples disclosed herein, a cost-effective organic solderability preservative (OSP) surface finish (as an alternative to the aforementioned known ENEPIG) can be utilized in combination with a microball solder alloy composition including indium, such as tin copper indium (SnCuIn), for example. In particular, the utilization of indium in the microball structure has demonstrated a considerable improvement in mitigation of electron migration. Additionally or alternatively, elements such as nickel, germanium, silver, etc. can be utilized in the microball structure. Examples can also enable glass core structures with increased resistance to breakage. Further, the aforementioned utilization of the OSP surface finish can reduce and/or prevent oxidation typically associated with copper to provide an improved surface finish.

As used herein, the term “microball” refers to a metallic interconnect component, object and/or body of solder that is coupled to a metallic pad or contact of a device such as a packaging substrate or interposer to at least partially define an electrical conductive path therebetween. Accordingly, the term “microball” can refer to the component, the object and/or the body of solder in its original produced form (e.g., a round original form structure) or an altered shape, such as a bump formed as a result of a reflow process, for example. As used herein, the term “first level interconnect” or “FLI” refers to a connection that is formed between a die and some other substrate (e.g., another die, an interposer, or a package substrate, etc.).

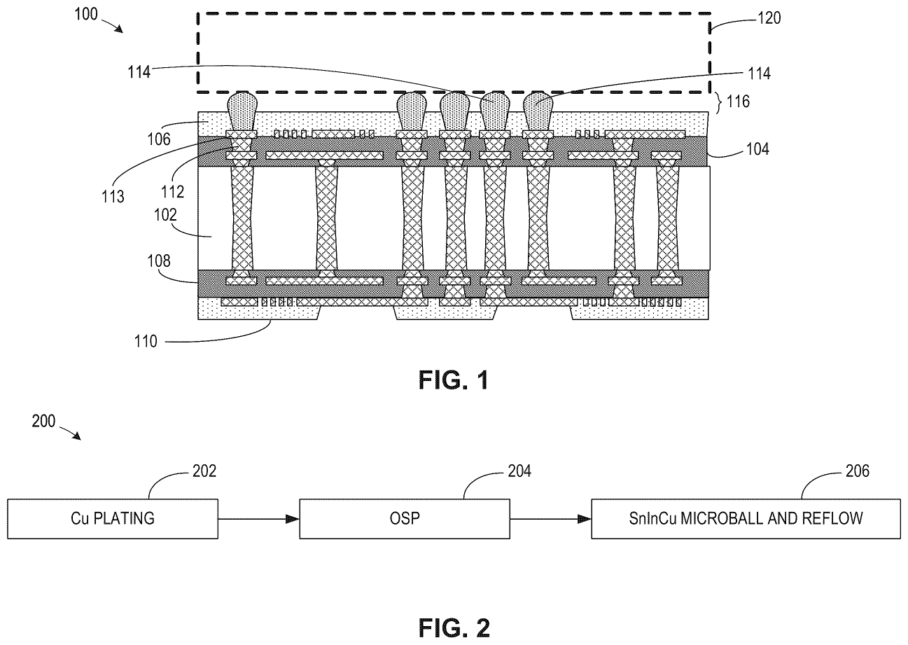

FIG. 1 is a cross sectional view of an example semiconductor package (e.g., a die package, a die chip, a chip package, a semiconductor device, an integrated circuit (IC) package, etc.) 100 in accordance with teachings of this disclosure. The semiconductor package 100 of the illustrated example includes a glass substrate (e.g., a glass core, a glass layer, etc.) 102, a first example buildup structure (e.g., a buildup layer structure, a layered buildup structure, buildup material, etc.) 104, a first example dielectric (e.g., a dielectric substrate, a dielectric layer, etc.) 106, a second example buildup structure 108, a second example dielectric 110, interconnects 112 that define and/or include contact pads 113, and metal interconnects 114, which are implemented as microballs that define a microball array (e.g., a microball grid array) 116, for example. In this example the microballs 114 are at least partially composed of indium (e.g., the microballs 114 are doped with indium).

According to examples disclosed herein, the semiconductor package 100 implements glass core technology for improved signal isolation and high frequency performance. To that end, the glass substrate 102 is positioned and/or placed between the first buildup structure 104 and the second buildup structure 108. As can be seen in the illustrated example of FIG. 1, the interconnects 112 can at least partially extend through a depth of the glass substrate 102. In turn, the example contact pads 113 defined by the interconnects 112 are electrically and/or communicatively coupled to the microballs 114. In some examples, the semiconductor package 100 is coupled to at least one die (e.g., at least one microprocessor die) 120 via the microballs 114.

While the example of FIG. 1 is shown in the context of a glass core, examples disclosed herein can be applied to any appropriate other substrate and/or substrate technology, including, but not limited to, organic substrates, etc. In other words, examples disclosed herein can improve electromigration mitigation for a wide variety of applications.

FIG. 2 is an example process flow 200 to produce examples disclosed herein. In the illustrated example of FIG. 2, at block 202, a pad (e.g., the pad 113) is plated with copper to define a plated copper pad. However, any other appropriate plating and/or material can be implemented instead.

At block 204 an OSP finish is applied to the copper-plated pad. The OSP can include a water-based organic compound including, but not limited to, benzotriazoles, imidazoles, benzimidazole, etc. According to examples disclosed herein, the OSP finish is applied with a thickness of 100-1000 nanometers (nm) (e.g., 100 nm-500 nm, 500 nm-1000 nm, etc.) such that the OSP prevents copper oxidation to facilitate improved solderability.

At block 206, a microball at least partially composed of tin, indium and copper is provided to (e.g., placed on, dispensed to, etc.) the copper pad. In this example, the microball is doped with the indium. However, the microball can have any other appropriate composition, mixture and/or processing. In this example, the microball is placed onto the copper pad. In turn, the microball undergoes a reflow process.

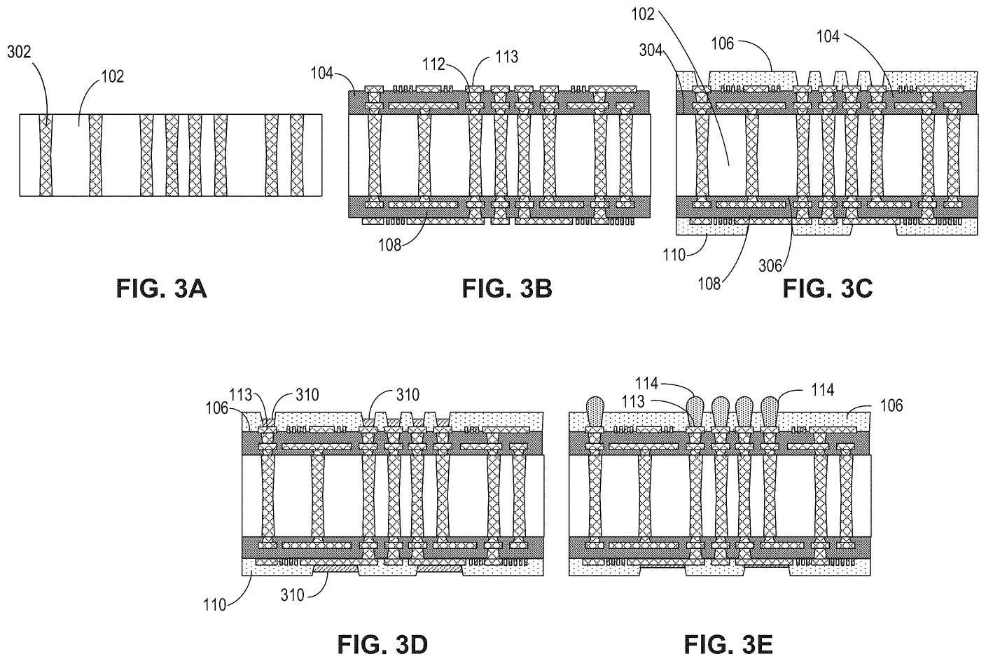

FIGS. 3A-3E depict example stages in a manufacturing process to produce examples disclosed herein. In particular, an example glass core structure is to be produced with indium-based microballs. Turning to FIG. 3A, the glass substrate 102 is defined with interconnects 302 extending therethrough. In particular, an etching process and chemical mechanical planarization (CMP) process are utilized.

FIG. 3B depicts the buildup structure 104 and the buildup structure 108, both of which are layered in this example. In the illustrated example of FIG. 3B the buildup structure 104 and the buildup structure 108 are defined on the glass substrate 102. In the illustrated example of FIG. 3B, layers of the buildup structure 104 and layers of the buildup structure correspond to a non-conductive dielectric material. Further, the interconnects 112, as well as the corresponding contact pads 113, are defined in and/or supported by the buildup structure 104. In this example, the contact pads 113 are at least partially composed of and/or plated with copper. However, the contact pads 113 can include and/or be composed of or plated with any other appropriate material, conductor and/or metal.

Turning to FIG. 3C, according to examples disclosed herein, the aforementioned example dielectric 106 is defined on, placed and/or patterned onto the buildup structure 104 on a first side 304 of the glass substrate 102 and, like wise, the dielectric 110 is patterned onto the buildup structure 108 on a second side 306 of the glass substrate 102 that is opposite to the first side 304. In this example, the dielectric substrate (e.g., the dielectric 106 and/or the dielectric 110) is at least partially composed of silicon.

FIG. 3D depicts OSP being placed and/or provided onto the aforementioned contact pads 113, thereby defining an OSP layer 310. In this example, the OSP layer 310 is only applied to the contact pads 113. In some examples, the OSP layer 310 is applied utilizing a mask to enable the OSP layer to be placed on the contact pads 113 as opposed to covering any of the dielectric 106 or the dielectric 110.

In the illustrated example of FIG. 3E, the microballs 114 are placed onto and/or adjacent the contact pads 113. In some examples, the microballs 114 are aligned and/or placed via openings and/or apertures in the dielectric 106. Additionally or alternatively, the microballs 114 are placed via a fixture (e.g., a fixture with apertures to guide placement of the microballs 114). In this example, a reflow process is utilized such that the example depicted glass core structure shown in FIG. 3A is heated, thereby causing the microballs 114 to form bumps on respective ones of the contact pads 113. Subsequently, a deflux process is utilized to clean and/or remove any residue resultant from the aforementioned steps/processes.

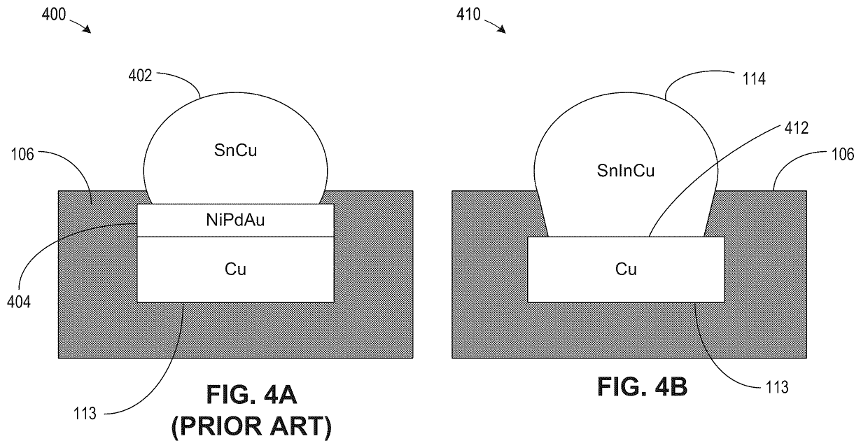

FIGS. 4A and 4B are detailed cross-sectional views of microball implementations. Turning to FIG. 4A, a known microball structure 400 is shown. In this known implementation, the microball 402 includes a tin copper (SnCu) composition and is placed onto the copper contact pad 113 with an ENEPIG layer 404 placed therebetween.

FIG. 4B depicts an example microball structure 410 in accordance with teachings of this disclosure. In contrast to the known microball structure 400 shown in FIG. 4A, the example microball structure 410 contacts the pad 113 and does not include an ENEPIG layer and the microball 114 includes a composition of tin, indium, and copper as opposed to a composition of tin and copper. Additionally or alternatively, the microball 114 can have a solder composition that includes nickel, germanium or silver, or any other appropriate material. In contrast to the known implementation shown in FIG. 4A, the example microball 114 includes indium, which can be highly advantageous in mitigating electromigration. In this example, the dielectric 106 laterally covers and/or surrounds at least a portion of a side (e.g., a side surface) and/or lateral sides of the microball 114. In some other examples, ENEPIG (e.g., an ENEPIG layer) is placed between the microball 114 including indium and the contact pad 113. Additionally or alternatively, a thin (e.g., 1 nm-100 nm thickness) layer of OSP 412 is present between the microball 114 and the contact pad 113 (e.g., prior to reflow of the microball 114). In While the examples disclosed herein are shown in the context of microballs, examples disclosed herein can be applied to any appropriate interconnect, reflow connection and/or solder ball at any appropriate size scale.

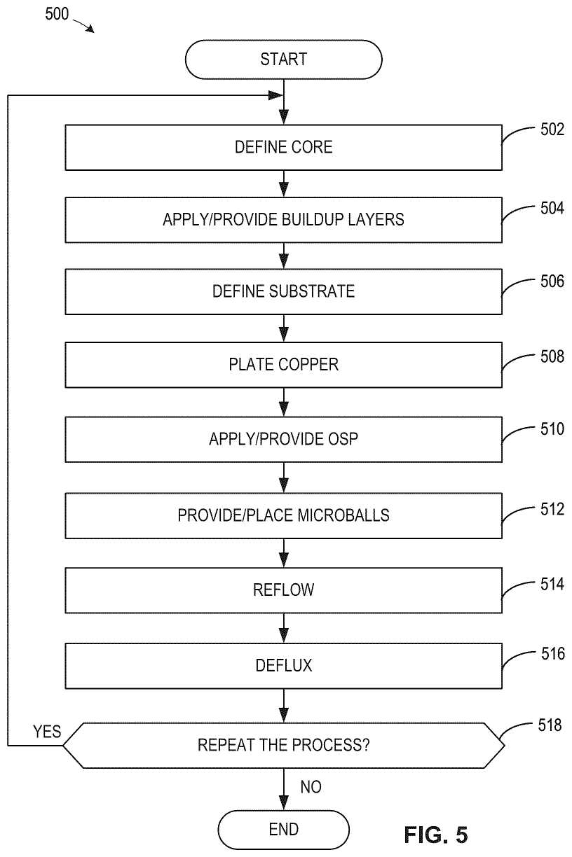

FIG. 5 is a flowchart representative of an example method 500 to produce examples disclosed herein. In this example, a glass core semiconductor package, such as the example semiconductor package 100 shown in FIG. 1, is to be produced.

At block 502, a glass core or substrate (e.g., the example glass substrate 102) is produced and/or defined. In some examples, apertures are defined in the glass substrate such that interconnects (e.g., copper interconnects) extend therethrough.

At block 504, buildup layers and/or a buildup structure (e.g., the buildup structure 104) are applied and/or defined onto the aforementioned glass substrate. In this example, the buildup layers are provided with interconnects that are electrically coupled to the interconnects of the glass substrate.

At block 506, a silicon-based substrate (e.g., the dielectric 106) is defined and/or provided onto respective ones of the buildup structures. According to examples disclosed herein, a lithography process is utilized to at least partially define the silicon-based substrate. Additionally or alternatively, a composite encapsulation of the substrate is implemented. In some examples, the silicon-based substrate or surface insulation material at least partially surrounds lateral ends and/or sides of interconnects and/or contact pads. In other words, the silicon-based substrate or the surface insulation material may at least partially cover lateral portions of the interconnects and/or the contact pads.

At block 508, copper is plated onto the contact pads (e.g., the contact pads 113) that are exposed via openings and/or apertures of the substrate. However, any other appropriate material and/plating can be implemented instead.

At block 510, an OSP is applied to the contact pads, thereby forming OSP layers that cover the contact pads. In the illustrated example of FIG. 5, the OSP is applied as a surface finish to only cover the contact pads (e.g., the OSP is selectively applied to the contact pads via a mask). In this example, the thickness of the OSP is approximately 100 nm-1000 nm (e.g., 100 nm-300 nm, 100 nm-500 nm, 500 nm-700 nm, 700 nm-1000 nm, etc.). According to examples disclosed herein, the OSP can prevent oxidation of the copper of the contact pads. Additionally or alternatively, ENEPIG or other metal layer is applied to the contact pads to cover and/or form a layer over the contact pads.

At block 512, microballs (e.g., the microballs 114) are placed/provided onto the contact pads. In this example, ones of the microballs are placed onto and/or positioned proximate apertures of the silicon-based dielectric or surface insulation material. In some examples, the microballs are dispensed and aligned via a fixture such that the fixture can guide the microballs to their respective intended positions. Further, a flux (e.g., a tacky flux) can be applied between the microballs and the respective contact pads.

At block 514, a reflow process is implemented to heat and reflow the microballs. In some examples, the microballs are reflowed to define bumps on the contact pads. Further, an additional reflow process can be utilized when coupling the glass core semiconductor package to a die or other semiconductor package, for example.

At block 516, a deflux/defluxing process is implemented to clean flux residue that can result from reflow process(es). According to examples disclosed herein, the residue can correspond to the OSP, the flux and/or substances formed or deposited onto the dielectric.

At block 518, in some examples, it is determined whether to repeat the process such that an additional device, component and/or package with a microball solder array can be produced. If the process is to be repeated (block 518), control of the process returns to block 502. Otherwise, the process ends. This determination may be based on whether additional glass core-based semiconductor packages are to be produced.

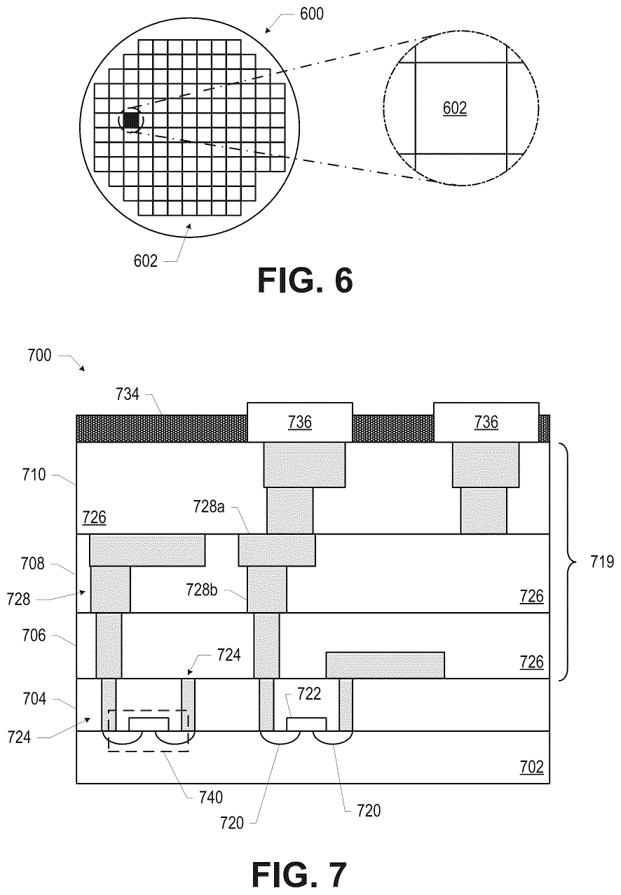

The example microball structures disclosed herein may be included in any suitable electronic component. FIGS. 6-10 illustrate various examples of apparatus that may include and/or be associated with the microball structures disclosed herein.

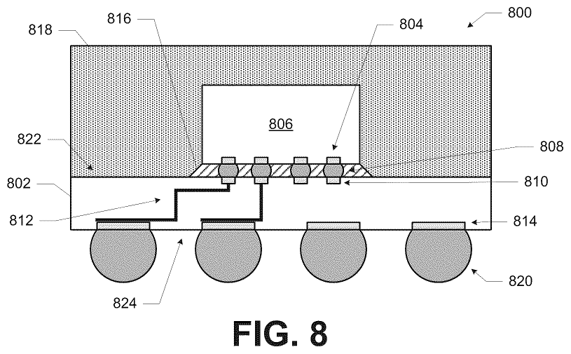

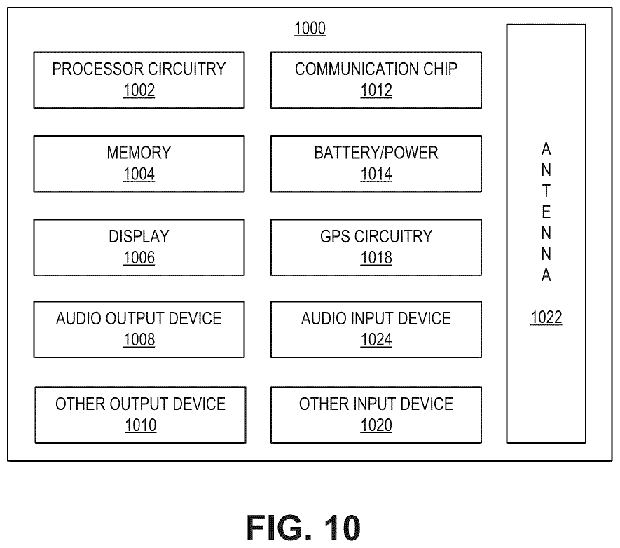

FIG. 6 is a top view of a wafer 600 and dies 602 that may be included in an IC package whose substrate includes one or more microball structures (e.g., as discussed below with reference to FIG. 8) in accordance with any of the examples disclosed herein. The wafer 600 may be composed of semiconductor material and may include one or more dies 602 having circuitry. Each of the dies 602 may be a repeating unit of a semiconductor product. After the fabrication of the semiconductor product is complete, the wafer 600 may undergo a singulation process in which the dies 602 are separated from one another to provide discrete “chips.” The die 602 may include one or more transistors (e.g., some of the transistors 740 of FIG. 7, discussed below), supporting circuitry to route electrical signals to the transistors, passive components (e.g., traces, resistors, capacitors, inductors, and/or other circuitry), and/or any other components. In some examples, the die 602 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 602. For example, a memory array formed by multiple memory circuits may be formed on a same die 602 as programmable circuitry (e.g., the processor circuitry 1002 of FIG. 10) or other logic circuitry. Such memory may store information or instructions for use by the programmable circuitry. The example microball structures disclosed herein may be manufactured using a die-to-wafer assembly technique in which some dies are attached to a wafer 600 that include others of the dies, and the wafer 600 is subsequently singulated.

FIG. 7 is a cross-sectional side view of an IC device 700 that may be included in an IC package whose substrate includes one or more microball structures (e.g., as discussed below with reference to FIG. 8), in accordance with any of the examples disclosed herein. One or more of the IC devices 700 may be included in one or more dies 602 (FIG. 6). The IC device 700 may be formed on a die substrate 702 (e.g., the wafer 600 of FIG. 6) and may be included in a die (e.g., the die 702 of FIG. 7). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some examples, the die substrate 702 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an IC device 700 may be used. The die substrate 702 may be part of a singulated die (e.g., the dies 602 of FIG. 6) or a wafer (e.g., the wafer 600 of FIG. 6).

The IC device 700 may include one or more device layers 704 disposed on or above the die substrate 702. The device layer 704 may include features of one or more transistors 740 (e.g., metal oxide semiconductor field-effect transistors (MOSFETs)) formed on the die substrate 702. The device layer 704 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other examples, at least one of the metal layers that form the gate electrode may simply be a planar layer that is substantially parallel to the top surface of the die substrate 702 and does not include sidewall portions substantially perpendicular to the top surface of the die substrate 702. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of each transistor 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 720 may be formed using one or more alternate semiconductor materials such as germanium or a group III-V material or alloy. In further examples, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the IC device 700.

The interconnect structures 728 may be arranged within the interconnect layers 706-710 to route electrical signals according to a wide variety of designs (in particular, the arrangement is not limited to the particular configuration of interconnect structures 728 depicted in FIG. 7). Although a particular number of interconnect layers 706-710 is depicted in FIG. 7, examples of the present disclosure include IC devices having more or fewer interconnect layers than depicted.

In some examples, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page from the perspective of FIG. 7. The vias 728b may be arranged to route electrical signals in a direction of a plane that is substantially perpendicular to the surface of the die substrate 702 upon which the device layer 704 is formed. In some examples, the vias 728b may electrically couple lines 728a of different interconnect layers 706-710 together.

The interconnect layers 706-710 may include a dielectric material 726 disposed between the interconnect structures 728, as shown in FIG. 7. In some examples, the dielectric material 726 disposed between the interconnect structures 728 in different ones of the interconnect layers 706-710 may have different compositions; in other examples, the composition of the dielectric material 726 between different interconnect layers 706-710 may be the same.

A first interconnect layer 706 (referred to as Metal 1 or “M1”) may be formed directly on the device layer 704. In some examples, the first interconnect layer 706 may include lines 728a and/or vias 728b, as shown. The lines 728a of the first interconnect layer 706 may be coupled with contacts (e.g., the S/D contacts 724) of the device layer 704.

A second interconnect layer 708 (referred to as Metal 2 or “M2”) may be formed directly on the first interconnect layer 706. In some examples, the second interconnect layer 708 may include vias 728b to couple the lines 728a of the second interconnect layer 708 with the lines 728a of the first interconnect layer 706. Although the lines 728a and the vias 728b are structurally delineated with a line within each interconnect layer (e.g., within the second interconnect layer 708) for the sake of clarity, the lines 728a and the vias 728b may be structurally and/or materially contiguous (e.g., simultaneously filled during a dual-damascene process) in some examples.

A third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some examples, the interconnect layers that are “higher up” in the metallization stack 719 in the IC device 700 (i.e., further away from the device layer 704) may be thicker.

The IC device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to other external devices. For example, solder bonds may be formed on the one or more conductive contacts 736 to mechanically and/or electrically couple a chip including the IC device 700 with another component (e.g., a circuit board). The IC device 700 may include additional or alternate structures to route the electrical signals from the interconnect layers 706-710; for example, the conductive contacts 736 may include other analogous features (e.g., posts) that route the electrical signals to external components.

FIG. 8 is a cross-sectional view of an example IC package 800 that may include one or more microball structures. The package substrate 802 may be formed of a dielectric material, and may have conductive pathways extending through the dielectric material between upper and lower faces 822, 824, or between different locations on the upper face 822, and/or between different locations on the lower face 824. These conductive pathways may take the form of any of the interconnects 728 discussed above with reference to FIG. 7. In some examples, any number of microball structures (with any suitable structure) may be included in a package substrate 802. In some examples, no microball structures may be included in the package substrate 802.

The IC package 800 may include a die 806 coupled to the package substrate 802 via conductive contacts 804 of the die 806, first-level interconnects 808, and conductive contacts 810 of the package substrate 802. The conductive contacts 810 may be coupled to conductive pathways 812 through the package substrate 802, allowing circuitry within the die 806 to electrically couple to various ones of the conductive contacts 814 or to the microball structures (or to other devices included in the package substrate 802, not shown). The first-level interconnects 808 illustrated in FIG. 8 are solder bumps, but any suitable first-level interconnects 808 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

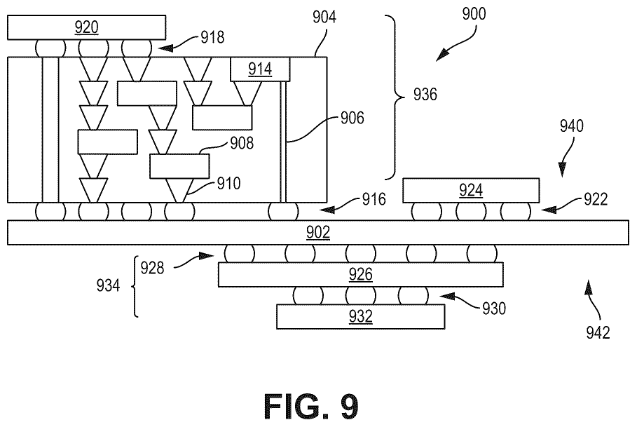

In some examples, an underfill material 816 may be disposed between the die 806 and the package substrate 802 around the first-level interconnects 808, and a mold compound 818 may be disposed around the die 806 and in contact with the package substrate 802. In some examples, the underfill material 816 may be the same as the mold compound 818. Example materials that may be used for the underfill material 816 and the mold compound 818 are epoxy mold materials, as suitable. Second-level interconnects 820 may be coupled to the conductive contacts 814. The second-level interconnects 820 illustrated in FIG. 8 are solder balls (e.g., for a ball grid array arrangement), but any suitable second-level interconnects 820 may be used (e.g., pins in a pin grid array arrangement or lands in a land grid array arrangement). The second-level interconnects 820 may be used to couple the IC package 800 to another component, such as a circuit board (e.g., a motherboard), an interposer, or another IC package, as known in the art and as discussed below with reference to FIG. 9.

In FIG. 8, the IC package 800 is a flip chip package, and includes microball structures in the package substrate 802. The number and location of microball structures in the package substrate 802 of the IC package 800 is simply illustrative, and any number of microball structures (with any suitable structure) may be included in a package substrate 802. In some examples, no microball structures may be included in the package substrate 802. The die 806 may take the form of any of the examples of the die 1002 discussed herein (e.g., may include any of the examples of the IC device 700). In some examples, the die 806 may include and/or be coupled to one or more microball structures (e.g., as discussed above with reference to FIG. 6 and FIG. 7); in other examples, the die 806 may not include any microball structures.

Although the IC package 800 illustrated in FIG. 8 is a flip chip package, other package architectures may be used. For example, the IC package 800 may be a ball grid array (BGA) package, such as an embedded wafer-level ball grid array (eWLB) package. In another example, the IC package 800 may be a wafer-level chip scale package (WLCSP) or a panel fanout (FO) package. Although a single die 806 is illustrated in the IC package 800 of FIG. 8, an IC package 800 may include multiple dies 806 (e.g., with one or more of the multiple dies 806 coupled to microball structures included in the package substrate 802). An IC package 800 may include additional passive components, such as surface-mount resistors, capacitors, and inductors disposed on the first face 822 or the second face 824 of the package substrate 802. More generally, an IC package 800 may include any other active or passive components known in the art.

FIG. 9 is a cross-sectional side view of an IC device assembly 900 that may include the microball structures disclosed herein. In some examples, the IC device assembly 900 corresponds to substrates having the microball structures. The IC device assembly 900 includes a number of components disposed on a circuit board 902 (which may be, for example, a motherboard). The IC device assembly 900 includes components disposed on a first face 940 of the circuit board 902 and an opposing second face 942 of the circuit board 902; generally, components may be disposed on one or both faces 940 and 942.

In some examples, the circuit board 902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 902. In other examples, the circuit board 902 may be a non-PCB substrate.

The IC device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), male and female portions of a socket, an adhesive, an underfill material, and/or any other suitable electrical and/or mechanical coupling structure.

The package-on-interposer structure 936 may include an IC package 920 coupled to an interposer 904 by coupling components 918. The coupling components 918 may take any suitable form for the application, such as the forms discussed above with reference to the coupling components 916. Although a single IC package 920 is shown in FIG. 9, multiple IC packages may be coupled to the interposer 904; indeed, additional interposers may be coupled to the interposer 904. The interposer 904 may provide an intervening substrate used to bridge the circuit board 902 and the IC package 920. The IC package 920 may be or include, for example, a die (the die 602 of FIG. 6), an IC device (e.g., the IC device 700 of FIG. 7), or any other suitable component. Generally, the interposer 904 may spread a connection to a wider pitch or reroute a connection to a different connection. For example, the interposer 904 may couple the IC package 920 (e.g., a die) to a set of BGA conductive contacts of the coupling components 916 for coupling to the circuit board 902. In the example illustrated in FIG. 9, the IC package 920 and the circuit board 902 are attached to opposing sides of the interposer 904; in other examples, the IC package 920 and the circuit board 902 may be attached to a same side of the interposer 904. In some examples, three or more components may be interconnected by way of the interposer 904.

In some examples, the interposer 904 may be formed as a PCB, including multiple metal layers separated from one another by layers of dielectric material and interconnected by electrically conductive vias. In some examples, the interposer 904 may be formed of an epoxy resin, a fiberglass-reinforced epoxy resin, an epoxy resin with inorganic fillers, a ceramic material, or a polymer material such as polyimide. In some examples, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through-silicon vias (TSVs) 906. The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The IC device assembly 900 may include an IC package 924 coupled to the first face 940 of the circuit board 902 by coupling components 922. The coupling components 922 may take the form of any of the examples discussed above with reference to the coupling components 916, and the IC package 924 may take the form of any of the examples discussed above with reference to the IC package 920.

The IC device assembly 900 illustrated in FIG. 9 includes a package-on-package structure 934 coupled to the second face 942 of the circuit board 902 by coupling components 928. The package-on-package structure 934 may include a first IC package 926 and a second IC package 932 coupled together by coupling components 930 such that the first IC package 926 is disposed between the circuit board 902 and the second IC package 932. The coupling components 928, 930 may take the form of any of the examples of the coupling components 916 discussed above, and the IC packages 926, 932 may take the form of any of the examples of the IC package 920 discussed above. The package-on-package structure 934 may be configured in accordance with any of the package-on-package structures known in the art.

FIG. 10 is a block diagram of an example electrical device 1000 that may include one or more of the example microballs structures disclosed herein. For example, any suitable ones of the components of the electrical device 1000 may include one or more of the device assemblies 900, IC devices 700, or dies 602 disclosed herein, and may be arranged with the example microball structures. A number of components are illustrated in FIG. 10 as included in the electrical device 1000, but any one or more of these components may be omitted or duplicated, as suitable for the application. In some examples, some or all of the components included in the electrical device 1000 may be attached to one or more motherboards. In some examples, some or all of these components are fabricated onto a single system-on-a-chip (SoC) die.

Additionally, in various examples, the electrical device 1000 may not include one or more of the components illustrated in FIG. 10, but the electrical device 1000 may include interface circuitry for coupling to the one or more components. For example, the electrical device 1000 may not include a display 1006, but may include display interface circuitry (e.g., a connector and driver circuitry) to which a display 1006 may be coupled. In another set of examples, the electrical device 1000 may not include an audio input device 1024 (e.g., microphone) or an audio output device 1008 (e.g., a speaker, a headset, earbuds, etc.), but may include audio input or output device interface circuitry (e.g., connectors and supporting circuitry) to which an audio input device 1024 or audio output device 1008 may be coupled.

The electrical device 1000 may include programmable circuitry 1002 (e.g., one or more processing devices). The programmable circuitry 1002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1000 may include a memory 1004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1004 may include memory that shares a die with the programmable circuitry 1002. This memory may be used as cache memory and may include embedded dynamic random access memory (eDRAM) or spin transfer torque magnetic random access memory (STT-MRAM).

In some examples, the electrical device 1000 may include a communication chip 1012 (e.g., one or more communication chips). For example, the communication chip 1012 may be configured for managing wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1012 may operate in accordance with other wireless protocols in other examples. The electrical device 1000 may include an antenna 1022 to facilitate wireless communications and/or to receive other wireless communications (such as AM or FM radio transmissions).

In some examples, the communication chip 1012 may manage wired communications, such as electrical, optical, or any other suitable communication protocols (e.g., the Ethernet). As noted above, the communication chip 1012 may include multiple communication chips. For instance, a first communication chip 1012 may be dedicated to shorter-range wireless communications such as Wi-Fi or Bluetooth, and a second communication chip 1012 may be dedicated to longer-range wireless communications such as global positioning system (GPS), EDGE, GPRS, CDMA, WiMAX, LTE, EV-DO, or others. In some examples, a first communication chip 1012 may be dedicated to wireless communications, and a second communication chip 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display 1006 (or corresponding interface circuitry, as discussed above). The display 1006 may include any visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any device that generates an audible indicator, such as speakers, headsets, or earbuds.

The electrical device 1000 may include an audio input device 1024 (or corresponding interface circuitry, as discussed above). The audio input device 1024 may include any device that generates a signal representative of a sound, such as microphones, microphone arrays, or digital instruments (e.g., instruments having a musical instrument digital interface (MIDI) output).

The electrical device 1000 may include a GPS circuitry 1018. The GPS circuitry 1018 may be in communication with a satellite-based system and may receive a location of the electrical device 1000, as known in the art.

The electrical device 1000 may include any other output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include any other input device 1020 (or corresponding interface circuitry, as discussed above). Examples of the other input device 1020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

Example methods, apparatus, systems, and articles of manufacture to interconnects that are resistant to electromigration are disclosed herein. Further examples and combinations thereof include the following:

Example 1 includes an integrated circuit (IC) package comprising a dielectric substrate, a contact pad at least partially extending through or positioned on the dielectric substrate, the contact pad including copper, and a metal interconnect coupled to the contact pad, the interconnect including indium.

Example 2 includes the IC package as defined in example 1, further including a glass substrate.

Example 3 includes the IC package as defined in example 2, wherein a second metal interconnect associated with the contact pad extends through the glass substrate.

Example 4 includes the IC package as defined in any of examples 1 to 3, further including an electroless nickel/electroless palladium/immersion gold (ENEPIG) layer between the contact pad and the interconnect.

Example 5 includes the IC package as defined in any of examples 1 to 4, further including a die coupled to the interconnect.

Example 6 includes the IC package as defined in any of examples 1 to 5, wherein the interconnect includes a microball.

Example 7 includes the IC package as defined in any of examples 1 to 6, wherein the interconnect further includes tin and copper.

Example 8 includes the IC package as defined in any of examples 1 to 7, further including an organic solderability preservative (OSP) layer between the interconnect and the contact pad.

Example 9 includes a die chip comprising a die, a package substrate supporting the die, and a microball array electrically interconnecting the die and the package substrate, ones of the microball array including indium, tin and copper.

Example 10 includes the die chip as defined in example 9, wherein the die is a first die, and further including a second die electrically coupled to the package substrate.

Example 11 includes the die chip as defined in any of examples 9 or 10, wherein the package substrate includes a glass core.

Example 12 includes the die chip as defined in example 11, wherein interconnects of the package substrate extend through the glass core.

Example 13 includes the die chip as defined in any of examples 11 or 12, wherein the package substrate includes a first dielectric and a second dielectric, and wherein the glass core is positioned between the first dielectric and the second dielectric.

Example 14 includes the die chip as defined in example 13, further including first buildup material between the first dielectric and the glass core, and second buildup material between the second dielectric and the glass core.

Example 15 includes the die chip as defined in any of examples 9 to 14, wherein the ones of the microball array are coupled to the package substrate without an electroless nickel/electroless palladium/immersion gold (ENEPIG) layer or an intervening layer therebetween.

Example 16 includes the die chip as defined in any of examples 9 to 15, wherein the ones of the microball array include at least one of tin, copper, nickel, germanium or silver.

Example 17 includes a method comprising defining an interconnect on or within a dielectric substrate, plating the interconnect with copper, and placing a microball onto the interconnect, the microball including indium.

Example 18 includes the method as defined in example 17, further including applying an organic solderability preservative (OSP) to the interconnect.

Example 19 includes the method as defined in example 18, wherein the OSP is applied with a thickness of approximately 100 nanometers (nm) to 1000 nm onto the interconnect.

Example 20 includes the method as defined in any of examples 17 or 19, further including applying electroless nickel/electroless palladium/immersion gold (ENEPIG) to the interconnect.

Example 21 includes the method as defined in any of examples 17 to 20, further including reflowing the microball placed onto the interconnect.

Example 22 includes the method as defined in any of examples 17 to 21, further including coupling a die to the interconnect.

From the foregoing, it will be appreciated that example systems, methods, apparatus, and articles of manufacture have been disclosed that enable semiconductor packages and/or devices to have improved electron migration. As a result, examples disclosed herein can have greater reliability. In particular, it has been demonstrated that a lifetime of an interconnect may increase by a two-fold increase in lifetime compared to known implementations, for example. Further, examples disclosed herein can be advantageously used in implementations with glass substrates and/or glass cores, amongst other applications. According to examples disclosed herein, utilization of an OSP surface finish can provide breakage resistance for a glass substrate/core. In particular, application of OSP can mitigate the effects of shock and sway on the glass substrate/core. Further, examples disclosed herein have demonstrated significant increases in mean time to failure (MTTF).

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An integrated circuit (IC) package comprising:
a dielectric substrate;
a contact pad at least partially extending through or positioned on the dielectric substrate, the contact pad including copper; and
a metallic interconnect coupled to the contact pad, the interconnect including indium.

2. The IC package as defined in claim 1, further including a glass substrate.

3. The IC package as defined in claim 2, wherein a second metallic interconnect associated with the contact pad extends through the glass substrate.

4. The IC package as defined in claim 1, further including an electroless nickel/electroless palladium/immersion gold (ENEPIG) layer between the contact pad and the interconnect.

5. The IC package as defined in claim 1, further including a die coupled to the interconnect.

6. The IC package as defined in claim 1, wherein the interconnect includes a microball.

7. The IC package as defined in claim 1, wherein the interconnect further includes tin and copper.

8. The IC package as defined in claim 1, further including an organic solderability preservative (OSP) layer between the interconnect and the contact pad.

9. A die chip comprising:
a die;
a package substrate supporting the die; and
a microball array electrically interconnecting the die and the package substrate, ones of the microball array including indium.

10. The die chip as defined in claim 9, wherein the die is a first die, and further including a second die electrically coupled to the package substrate.

11. The die chip as defined in claim 9, wherein the package substrate includes a glass core.

12. The die chip as defined in claim 11, wherein interconnects of the package substrate extend through the glass core.

13. The die chip as defined in claim 11, wherein the package substrate includes a first dielectric and a second dielectric, and wherein the glass core is positioned between the first dielectric and the second dielectric.

14. The die chip as defined in claim 13, further including:
first buildup material between the first dielectric and the glass core; and
second buildup material between the second dielectric and the glass core.

15. The die chip as defined in claim 9, wherein the ones of the microball array are coupled to the package substrate without an electroless nickel/electroless palladium/immersion gold (ENEPIG) layer or an intervening layer therebetween.

16. The die chip as defined in claim 9, wherein the ones of the microball array include at least one of tin, copper, nickel, germanium or silver.

17. A method comprising:
defining an interconnect on or within a dielectric substrate;
plating the interconnect with copper; and
placing a microball onto the interconnect, the microball including indium.

18. The method as defined in claim 17, further including applying an organic solderability preservative (OSP) to the interconnect.

19. The method as defined in claim 18, wherein the OSP is applied with a thickness of approximately 100 nanometers (nm) to 1000 nm onto the interconnect.

20. The method as defined in claim 17, further including applying electroless nickel/electroless palladium/immersion gold (ENEPIG) to the interconnect.
